(19) United States
(12) Patent Application Publication
(10) Pub. No.: US 2007/0108374 A1
(43) Pub. Date: May 17, 2007

(54) PHOTOCURRENT AMPLIFIER CIRCUIT AND OPTICAL PICK-UP DEVICE

(75) Inventors: Hideo FUKUDA, Osaka (JP); Shinichi MIYAMOTO, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/554,742

(22) Filed: Oct. 31, 2006

(30) Foreign Application Priority Data
Nov. 11, 2005 (JP) 2005/328089

(51) Int. Cl. H03F 3/08

(52) U.S. Cl. 250/214 A

(57) ABSTRACT

A photocurrent amplifier circuit which freely combines photocurrent obtained by light receiving devices and amplifies the combined photocurrents includes: light receiving devices which generate photocurrent in accordance with the amount of light received; amplifier circuits; and device selector switches which are connected between the amplifier circuits and the light receiving devices, in which the number of device selector switches connected to each of the light receiving devices is the same as the number of the amplifier circuits.

### BACKGROUND OF THE INVENTION

(1) Field of the Invention

The present invention relates to a photocurrent amplifier circuit and an optical pick-up device in which the photocurrent amplifier circuit is used, and particularly to a technology which realizes a small-scale photocurrent amplifier circuit.

(2) Description of the Related Art

These days, optical disc media such as Compact Discs (CDs) and Digital Versatile Discs (DVDs) have been widely used for recording large amount of digital information such as video and audio. As is commonly known, in order to read and/or write information from and/or to these various types of optical disc media (hereinafter simply referred to as media), laser lights of different wavelengths are used depending on the type of media.

A conventional small-scale optical pick-up device compliant with both CDs and DVDs typically includes a two-wavelength semiconductor laser device which is used as a light source and a single optical system which is used in common for laser beams of the both wavelengths. Light receiving devices placed in the positions which differ in accordance with the distance between the emitting points of the lasers having the respective wavelengths, and perform photo-electric conversion of reflected laser light from the medium projected through the optical system. An electric signal is thus obtained, and the obtained electric signal is amplified and outputted.

As a light receiving amplifier device suitable for such an optical pick-up device, a light receiving amplifier device, which selectively obtains one output by switching preamplifiers placed for each of the light receiving devices of different wavelengths, is well-known (see FIG. 3 and FIG. 4 of Patent Reference 1: Japanese Laid-Open Patent Application No. 2004-22051).

### SUMMARY OF THE INVENTION

Although the conventional light receiving amplifier device is suitable for selectively outputting one of the signals obtained from a plurality of light receiving devices, it is not necessarily suitable for an application to output signals of adopted combinations. The application, for instance, can be seen when the push-pull method and the phase difference detection method, both well-known technologies for tracking detection, are dynamically used.

In the push-pull method, two sub-beams which are distantly positioned in the tangential direction are projected onto a media. Tracking detection is performed by utilizing the fact that imbalance of the reflected sub-beams arises in accordance with the direction of tracking errors (toward an inner track or an outer track).

In the phase difference detection method, tracking detection is performed by utilizing the fact that phase difference arises between the inner track side of the reflected sub-beams and the outer track side of the reflected sub-beams.

FIG. 3 is a diagram conceptually showing an example configuration of light receiving device which can be used in both methods. In this example, light receiving devices A and B are set to receive reflected light of the preceding sub-beam, and light receiving devices C and D are set to receive reflected succeeding sub-beam. In the push-pull method, intensity difference of light between (A+B) and (C+D) is used as a signal representing tracking errors, while in the phase difference detection method, the phase difference between (A+C) and (B+D) is used as a signal representing tracking errors.

The signals are calculated by adding signals from each of the photo electric devices using various combinations according to the detection methods, and it is easy to obtain the signal by processing each signal in operational amplifying circuits set for each combination. However, in such a case it is inevitable for the scale of the circuit to increase.

The present invention has been conceived in view of such circumstances, and the object of this invention is to provide a small-scale photocurrent amplifier circuit which can freely combine the photocurrents obtained from the light receiving devices and amplify the combined photocurrents.

In order to solve the above problem, the photocurrent amplifier circuit including: light receiving devices which generate photocurrent in accordance with the amount of light received; amplifier circuits; and device selector switches which are connected between the amplifier circuits and the light receiving devices, in which the number of device selector switches connected to each of the light receiving devices is the same as the number of the amplifier circuits.

In addition, the photocurrent amplifier circuit, in which each of the amplifier circuits is an operational amplifier, an input and output of which has a gain resistor connected therebetween, amplifies a current signal flowing from each of the light receiving devices to the gain resistor through each of the device selector switches which corresponds to each of the amplifier circuits.

In addition, The photocurrent amplifier circuit, further including a preamplifier circuit set for each of the light receiving devices which amplifies the photocurrent from a corresponding one of the light receiving devices.

The present invention can be realized not only as such a photocurrent amplifier circuit but also for an optical pick-up device equipped with the photocurrent amplifier circuit.

With the photocurrent amplifier circuit of the present invention, the photocurrent amplifier circuit can amplify the photocurrent flowing together to gain resistors through the device selector switches to be switched on. In addition, on/off of the device selector switches can be freely set, and thus, a small-scale photocurrent amplifier circuit which can freely combine the photocurrents generated in a plurality of light receiving devices and amplify the combined photocurrents can be realized.

### FURTHER INFORMATION ABOUT TECHNICAL BACKGROUND TO THIS APPLICATION

The disclosure of Japanese Patent Application No. 2005-328089 filed on Nov. 11th, 2005 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a circuit diagram showing an example of a photocurrent amplifier circuit of the first embodiment;

FIG. 2 is a circuit diagram showing an example of a photocurrent amplifier circuit of the second embodiment; and

FIG. 3 is a diagram conceptually showing a conventional configuration of a light receiving device.

### DESCRIPTION OF THE PREFERRED EMBODIMENT(S)

The embodiments of the present invention are described hereinafter with reference to the diagrams.

### First Embodiment

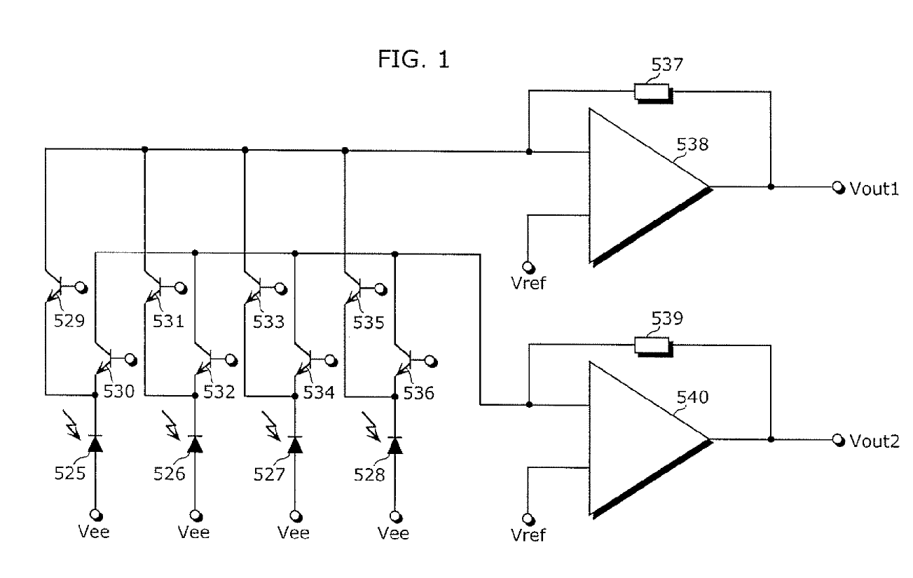

FIG. 1 is a circuit diagram showing an example of a photocurrent amplifier circuit according to the first embodiment of the present invention.

The photocurrent amplifier circuit is a circuit which freely combines photocurrents generated in the light receiving devices, amplifies the combined photocurrents. The photocurrent amplifier circuit is configured of light receiving devices 525 to 528, amplifier circuits 538 and 540, gain resistors 537 and 539, NPN transistors 529 to 536. Here, the NPN transistors 529 to 536 are examples of device selector switches. In accordance with the number of the amplifier circuits, two NPN transistors are placed for the respective light receiving devices 525 to 528 in the present embodiment. Each of the device selector switches are placed between the input of the amplifier circuit 538 and 540, respectively. Note that the amplifier circuits 538 and 540, for instance, may also be operational amplifiers.

The NPN transistors 529 to 536, the device selector switches, provide photocurrent, generated in the light receiving devices 525 to 528 which are connected to the NPN transistors 529 to 536, to the corresponding inputs of amplifier circuits, respectively.

The gain resistors 537 and 539 are feedback resistors respectively inserted to the negative feedback circuits of the amplifier circuits 538 and 540, and provide the photocurrent from the output of the corresponding amplifier circuit. The amplifier circuits 538 and 540 respectively amplify the photocurrents flowing in the gain resistors 537 and 539 to voltage signals and output the voltage signals.

The photocurrent amplifier circuit, for instance, is suitable for the optical pick-up devices having light receiving devices utilized for both the push-pull method and the phase difference method.

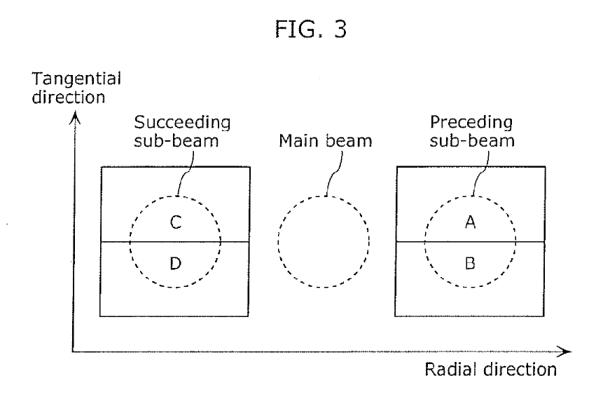

In the case where this photocurrent amplifier circuit is used for such an optical pick-up device, the light receiving devices A to D shown in FIG. 3 are the light receiving devices 525 to 528 shown in FIG. 1, respectively.

In the push-pull method, for example, by switching on the NPN transistors 529, 531, 534, and 536, while switching off the NPN transistors 530, 532, 533, and 535, a signal (A+B) is obtained from the amplifier circuit 538, together with a signal (C+D) from the amplifier circuit 540. The intensity difference between the two signals can be calculated in an external circuit which is not shown in the diagrams.

On the other hand, in the phase difference detection method, for example, by switching on the NPN transistors 529, 532, 533, and 536, while switching off the NPN transistors 530, 531, 534, and 535, a signal (A+C) is obtained from the amplifier circuit 538, together with a signal (B+D) from the amplifier circuit 540. The phase difference between the two signals can be calculated in the external circuit which is not shown in the diagram.

With this configuration, the photocurrents which flow together to the gain resistors 537 and 539 through the NPN transistors 529 to 536 when switched on can be amplified in the amplifier circuit 538 and 540. In addition, since on/off of the NPN transistors 529 to 536 can be freely set, a small-scale photocurrent amplifier circuit, which can freely combine the photocurrents obtained from the light receiving devices 525 to 528 and amplify the combined photocurrents can be realized.

### Second Embodiment

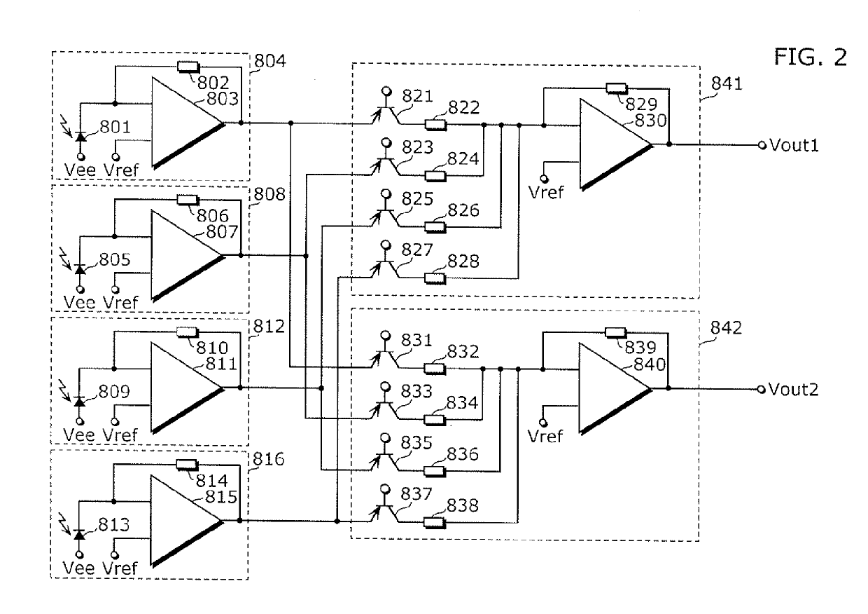

FIG. 2 is a circuit diagram showing an example of a photocurrent amplifier circuit according to the second embodiment of the present invention.

This photocurrent amplifier circuit is a circuit which freely combines the photocurrents generated in a plurality of the light receiving devices and amplifies the combined photocurrents. The photocurrent amplifier circuit is configured of light receiving circuits 804, 808, 812, and 816, and output amplifier circuits 841 and 842.

Each of the light receiving circuits 804, 808, 812, and 816 is a circuit which amplifies the photocurrents generated in the light receiving devices to voltage signals according to the amount of light received, and output the voltage signals. The light receiving circuit 804 is configured of a light receiving device 801, a resistor 802, and an operational amplifier 803. Here, the operational amplifier 803 is an example of the abovementioned preamplifier circuit which amplifies the photocurrent from the light receiving device to a voltage signal. Accordingly, the light receiving circuits 808, 812, and 816 are configured in the same manner.

The output amplifier circuits 841 and 842 are circuits which combine the signals from the light receiving circuits selected by the device selector switches and amplify the combined signals. The output amplifier circuit 841 is configured of: the PNP transistors 821, 823, 825, and 827; input resistors 822, 824, 826, and 828; and an amplifier circuit 830 in which a gain resistor 829 is connected between the input and the output. Here, the PNP transistors 821, 823, 825, and 827 are the examples of the device selector switches. Note that the amplifier circuit 830, for instance, may also be an operational amplifier.

In each of the PNP transistors 821, 823, 825, and 827 to be switched on, a current flow in accordance with the respective output voltages from the light receiving circuits 804, 808, 812, and 816, a reference voltage Vref, and respective input resistors 822, 824, 826, and 828. These currents flow together to the gain resistor 829, and are amplified as a voltage signal by the amplifier circuit 830.

With this configuration, an output corresponding to the total of current signals flowing in the PNP transistors 821, 823, 825, and 827 to be switched on can be obtained, while on/off of the PNP transistors 821, 823, 825, and 827 can be freely set. Thus, it is possible to obtain the result of the amplification from free combination of the photocurrents from the light receiving devices 801, 805, 809, and 813.

The configuration and operation of the output amplifier circuit 842 can be described in the same manner.

The photocurrent amplifier circuit, like the photocurrent amplifier circuits in the first embodiment, for instance, is suitable for an optical pick-up device having the light receiving devices, which can be used both for the push-pull method and the phase difference detection method as described in the Related Art.

In the case where the photocurrent amplifier circuit is used for such an optical pick-up device, the light receiving devices A to D are the light receiving devices 801, 805, 809, and 813 shown in the FIG. 2 respectively.

In the push-pull method, for instance, by switching on the PNP transistors 821, 823, 835, and 837, while switching off the PNP transistors 825, 827, 831, and 833, the signal (A+B) is obtained from the amplifier circuit 830, and the signal (C+D) is obtained from the amplifier circuit 840. The intensity difference between the two signals can be calculated in an external circuit which is not indicated in the diagram.

On the other hand, in the phase difference detection method, for instance, by switching on the PNP transistors 821, 825, 833, and 837, while switching off the PNP transistors 823, 827, 831, and 835, the signal (A+C) can be obtained from the amplifier circuit 830, and the signal (B+D) can be obtained from the amplifier circuit 840. The phase difference between the two signals can be calculated in an external circuit which is not indicated in the diagrams.

With this configuration, a small-scale photocurrent amplifier circuit which can freely combine the photocurrents obtained from the light receiving devices 801, 805, 809, and 813 and amplify the combined photocurrents can be implemented.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The photocurrent amplifier circuit of the present invention can be widely used as an amplifier circuit which can freely combine photocurrents obtained from a plurality of light receiving devices and amplify the combined photocurrents. In particular, the photocurrent amplifier circuit is suitable for a small-scale optical pick-up device which can dynamically utilizes the push-pull method and the phase difference detection method for tracking detection.

What is claimed is:

1. A photocurrent amplifier circuit comprising:
a plurality of light receiving devices which generate photocurrent in accordance with the amount of light received;
a plurality of amplifier circuits; and
a plurality of device selector switches which are connected between said plurality of amplifier circuits and said plurality of light receiving devices,
wherein the number of said device selector switches connected to each of said light receiving devices is the same as the number of said amplifier circuits.

2. The photocurrent amplifier circuit according to claim 1,
wherein each of said amplifier circuits is an operational amplifier, an input and output of which has a gain resistor connected therebetween, amplifies a current signal flowing from each of said light receiving devices to the gain resistor through each of said device selector switches which corresponds to each of said amplifier circuits.

3. The photocurrent amplifier circuit according to claim 1, further comprising
a preamplifier circuit set for each of said light receiving devices which amplifies the photocurrent from a corresponding one of said light receiving devices.
